(19) United States
(12) Patent Application Publication
(10) Pub. No.: US 2006/0249775 A1
(43) Pub. Date: Nov. 9, 2006

(54) SEMICONDUCTOR DEVICE WITH CONTACT AND METHOD OF FABRICATING THE SAME

(75) Inventor: Je-Min Park, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd, Gyeonggi-do (KR)

(21) Appl. No.: 11/381,985

(22) Filed: May 5, 2006

(30) Foreign Application Priority Data
May 6, 2005 (KR) 2005-37849

(51) Int. Cl. H01L 29/94

(52) U.S. Cl. 257/306

(57) ABSTRACT

A semiconductor device having a contact includes a semiconductor substrate having a core region, a first interlayer insulating layer disposed on the semiconductor substrate, a first interconnect line disposed on the first interlayer insulating layer, the first interconnect line extending in a first direction, and a conductive stud covering a sidewall of the first interconnect line, the conductive stud penetrating the first interlayer insulating layer to contact the semiconductor substrate.

### CROSS-REFERENCE TO RELATED APPLICATIONS

This application claims priority from Korean Patent Application No. 10-2005-0037849, filed on 6 May 2005. Korean Patent Application No. 10-2005-0037849 is incorporated by reference.

### BACKGROUND

1. Technical Field

This disclosure relates to a semiconductor device and a method of fabricating the same, and more particularly to a semiconductor device with a contact having a conductive stud formed in a core region and a method of fabricating the same.

2. Description of the Related Art

Highly integrated semiconductor devices have three-dimensional arrangements and interconnections. Accordingly, contacts that connect elements and interconnections of semiconductor devices may have different depths, even though the contacts may be formed using similar process steps. When forming many deep contacts, conductive studs may be employed to connect the contacts.

FIG. 1 is a plan diagram illustrating a contact in a core region of a semiconductor device formed using a conventional method. FIGS. 2A through 4A are sectional diagrams illustrating a cell region in a direction perpendicular to a word line. FIGS. 2B through 4B are sectional diagrams illustrating the cell region in a direction perpendicular to a bit line, and FIGS. 2C through 4C are sectional diagrams illustrating the contact portion of the core region.

Referring to FIGS. 1 through 2C, a device isolating layer 12 is formed within a semiconductor substrate 10 to define an active region. A first interlayer insulating layer 24 that covers a gate line 20 is formed on the semiconductor substrate 10. Then, a contact pad 28 contacting the semiconductor substrate 10 is self-aligned within the first interlayer insulating layer 24 of the cell region. Subsequently, a second interlayer insulating layer 30 is formed on the entire surface of the first interlayer insulating layer 24. A core contact 26, i.e., a conductive stud, penetrating the second interlayer insulating layer 30 and the first interlayer insulating layer 24 is formed in the core region.

Referring to FIGS. 3A through 3C, a bit line 34 is formed in the core region. The core region also includes a bit line structure 40 which is wider than the bit line 34 and contacts the core contact 26. Simultaneously, the bit line 34 with the second width is formed in the cell region. The bit line structure 40 includes a bit line material layer 40a, a shielding layer 40b and a spacer 40c. The bit line 34 includes a bit line material layer 34a, a shielding layer 34b and a spacer 34c. Thereafter, a third interlayer insulating layer 36 covering the bit line 34 is formed. A lower electrode contact 38 is self-aligned between the bit lines 34 of the cell region.

Referring to FIGS. 4A through 4C, a fourth interlayer insulating layer 42 is formed on the third interlayer insulating layer 36 of the core region. Then, the fourth interlayer insulating layer 42 and the shielding layer 40b of the bit line structure 40 are removed, and a conductive material is filled into the contact hole 46 contacting the bit line structure 40, thereby forming an interconnect contact 48. After forming a capacitor 44 on the lower electrode contact 38 of the cell region, a fifth interlayer insulating layer 50 is formed. A sacrificial insulating layer (not shown) may be used prior to forming the fifth interlayer insulating layer 50 when the capacitor 44 is formed.

As the integration density of the semiconductor device increases, the dimensions of the core contact 26 formed within the bit line structure 40 of the core region must decrease. Consequently, an overlap margin for an interconnection between the interconnect contact and the bit line is reduced. The core portion may be enlarged to increase the margin but this may result in an increased size of the semiconductor device.

Embodiments of the invention address these and other disadvantages of the conventional art.

### SUMMARY

Embodiments of the invention provide a contact of a semiconductor device with an improved overlap margin between an interconnect contact and an interconnect line, i.e., a bit line, in a core region.

Embodiments of the invention also provide a method of fabricating a contact of a semiconductor device for improving an overlap margin between an interconnect contact and an interconnect line, i.e., a bit line, in a core region.

### BRIEF DESCRIPTION OF THE DRAWINGS

The above and other features and advantages of the invention will become more apparent by describing in detail exemplary embodiments thereof with reference to the attached drawings.

FIG. 1 is a plan diagram illustrating a contact in a core region of a semiconductor device formed using a conventional method.

FIGS. 2A, 3A, and 4A are sectional diagrams illustrating the cell region of FIG. 1 in a direction perpendicular to a word line.

FIGS. 2B, 3B, and 4B are sectional diagrams illustrating the cell region of FIG. 1 in a direction perpendicular to a bit line.

FIGS. 2C, 3C, and 4C are sectional diagrams illustrating a contact portion of the core region of FIG. 1.

FIG. 5 is a plan diagram illustrating a core bit line formed in a core region of a semiconductor device according to some embodiments of the invention.

FIG. 6A is a sectional diagram illustrating a cell region of FIG. 5 in a direction perpendicular to a word line.

FIG. 6B is a sectional diagram illustrating the cell region of FIG. 5 in a direction perpendicular to a bit line.

FIG. 6C is a sectional diagram illustrating a contact portion of the core region of FIG. 5.

FIG. 7 is a plan diagram illustrating a conductive stud in the core region of FIG. 5 according to some embodiments of the invention.

FIG. 8A is a sectional diagram illustrating the cell region of FIG. 7 in a direction perpendicular to the word line.

FIG. 8B is a sectional diagram illustrating the cell region of FIG. 7 in a direction perpendicular to the bit line.

FIG. 8C is a sectional diagram illustrating the contact portion of the core region of FIG. 7.

FIG. 9 is a plan diagram illustrating an interconnect contact in the core region of FIG. 5 according to some embodiments of the invention.

FIG. 10A is a sectional diagram illustrating the cell region of FIG. 9 in a direction perpendicular to the word line.

FIG. 10B is a sectional diagram illustrating the cell region of FIG. 9 in a direction perpendicular to the bit line.

FIG. 10C is a sectional diagram illustrating the contact portion of the core region of FIG. 9.

FIGS. 11A, 12A, and 13A are sectional diagrams illustrating a cell region of a semiconductor device according to other embodiments of invention in a direction perpendicular to a word line.

FIGS. 11B, 12B, and 13B are sectional diagrams further illustrating the cell regions of FIGS. 11A, 12B, and 13B, respectively, but in a direction perpendicular to a bit line.

FIGS. 11C, 12C, and 13C are sectional diagrams illustrating the contact portion of the core region of the semiconductor device illustrated in FIGS. 11A-11B, 12A-12B, and 13A-13B.

### DETAILED DESCRIPTION

The inventive principles will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

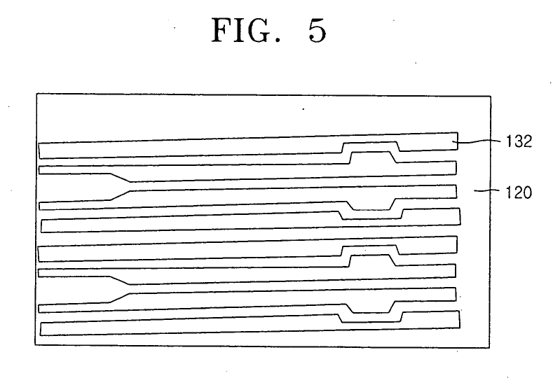

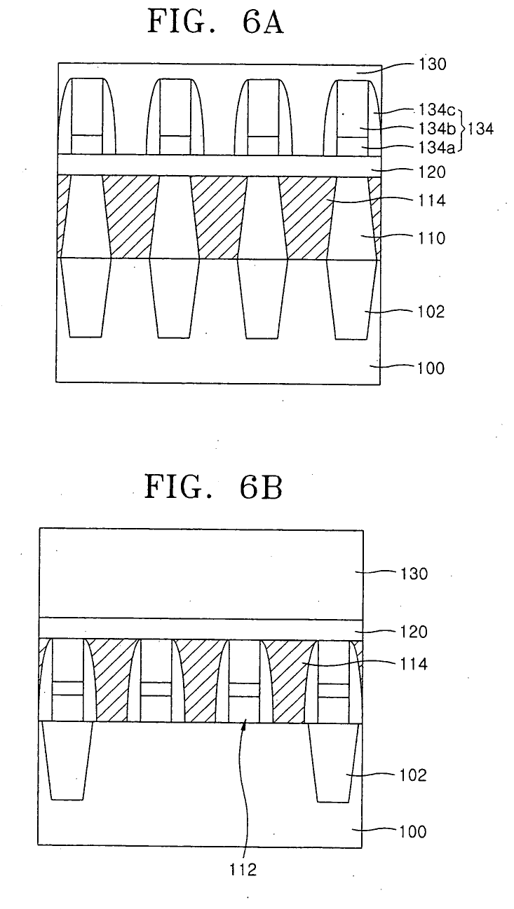

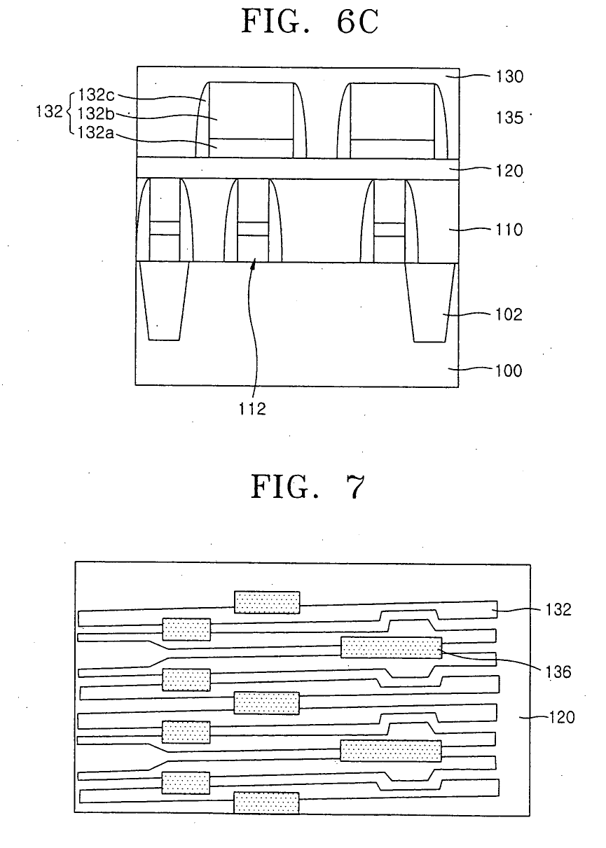

FIG. 5 is a plan diagram illustrating a first interconnect line 132 (hereinafter referred to as a “core bit line”) formed in a core region of a semiconductor device according to some embodiments of the invention. FIG. 6A is a sectional diagram illustrating a cell region of FIG. 5 in a direction perpendicular to a word line. FIG. 6B is a sectional diagram illustrating the cell region in a direction perpendicular to a bit line. FIG. 6C is a sectional diagram illustrating a contact portion of the core region.

Referring to FIGS. 5, 6A, 6B, and 6C, a device isolating layer 102 is formed within a semiconductor substrate 100 to define an active region. Then, a first interlayer insulating layer 110 covering a gate line 112 is formed on the semiconductor substrate 100. In the cell region, a contact pad 114 contacting the semiconductor substrate 100 is self-aligned within the first interlayer insulating layer 110. A second interlayer insulating layer 120 is formed on the entire surface of the first interlayer insulating layer 110.

In the core region, a core bit line 132 extending in a first direction is formed on the second interlayer insulating layer 120. In the cell region, the gate line 112 may extend in a second direction that is perpendicular to the first direction or it may extend in the first direction, like the gate line 112 of the core region. The core bit line 132 may be connected to a second interconnect line 134 in the cell region of the semiconductor substrate (hereinafter referred to as a “cell bit line”), the cell bit line 134 narrower than the core bit line 132. The core bit line 132 and the cell bit line 134 may be composed of bit line material layers 132a and 134a, capping layers 132b and 134b, and spacers 132c and 134c, respectively.

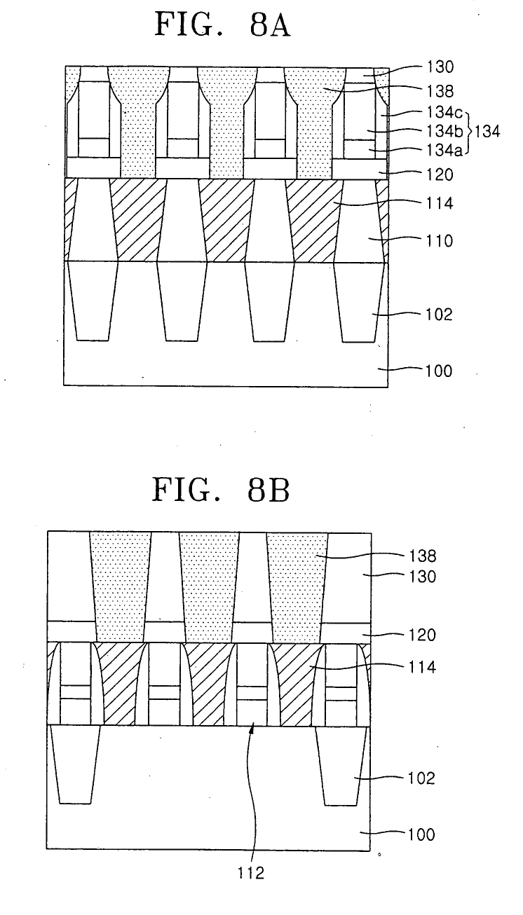

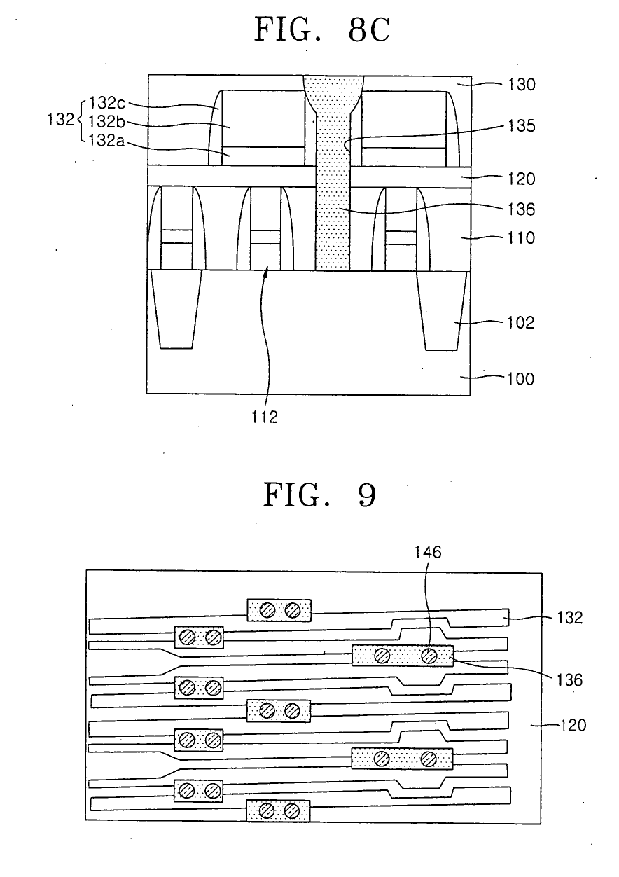

FIG. 7 is a plan diagram illustrating a conductive stud 136 in the core region of the device of FIG. 5 according to some embodiments of the invention. FIG. 8A is a sectional diagram illustrating the cell region of FIG. 7 in a direction perpendicular to the word line. FIG. 8B is a sectional diagram illustrating the cell region of FIG. 7 in a direction perpendicular to the bit line. FIG. 8C is a sectional diagram illustrating the contact portion of the core region of FIG. 7.

Referring to FIGS. 7, 8A, 8B, and 8C, the conductive stud 136 is formed in the core region by penetrating the core bit lines 132 to contact the semiconductor substrate 100. When forming the conductive stud 136, a third interlayer insulating layer 130 covering the core bit lines 132 is first formed. Then, a first photoresist pattern (not shown) for forming the conductive stud 136 is formed on the third interlayer insulating layer 130. Using the first photoresist pattern as an etch mask, the third interlayer insulating layer 130, the second interlayer insulating layer 120 and the first interlayer insulating layer 110 between the core bit lines 132 are removed, thereby forming a first contact hole 135 that exposes the semiconductor substrate 100. A conductive material is used to fill the first contact hole 135 and to form the conductive stud 136. Thus, the conductive stud 136 is self-aligned, and may be easily fabricated. Therefore, the core bit lines 132 can be arranged with a higher integration density than a bit line arrangement in a conventional core region. In this case, the conductive stud 136 may pass through the first interlayer insulating layer 110 between the underlying gate lines 112.

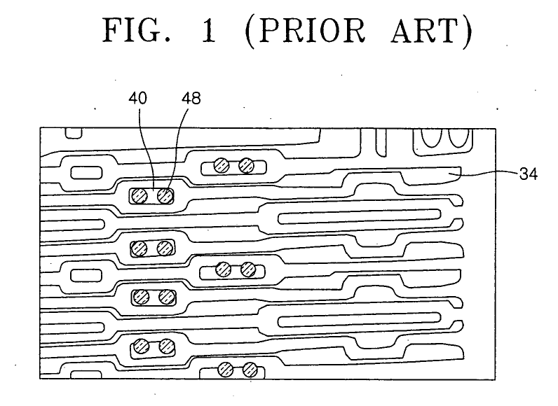

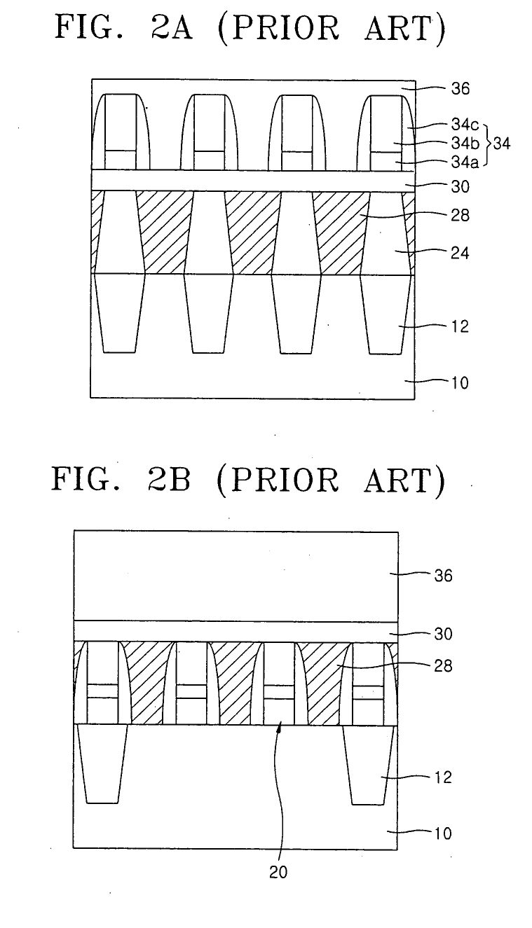

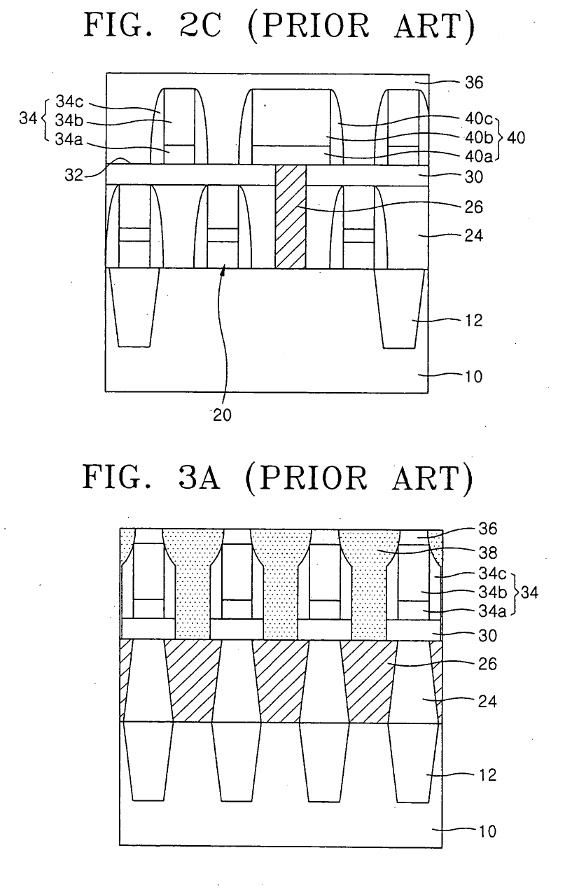

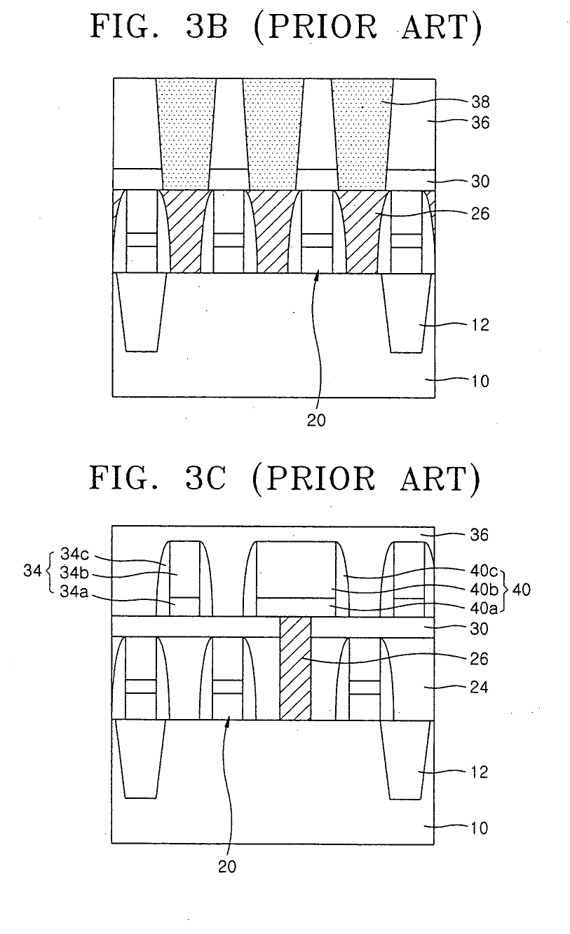

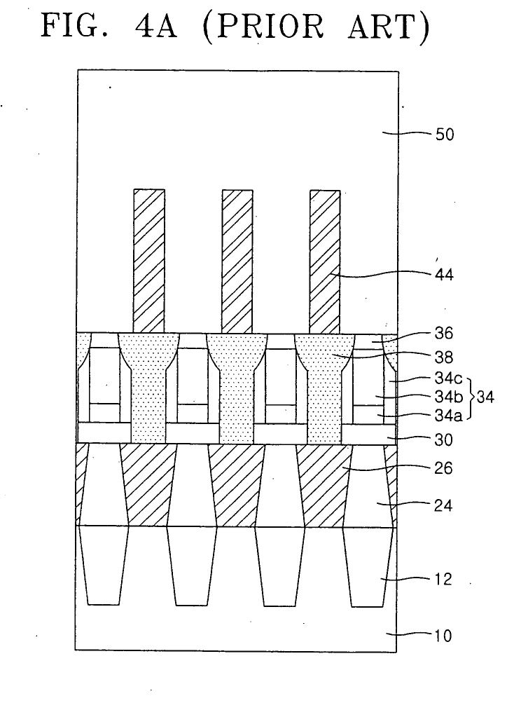

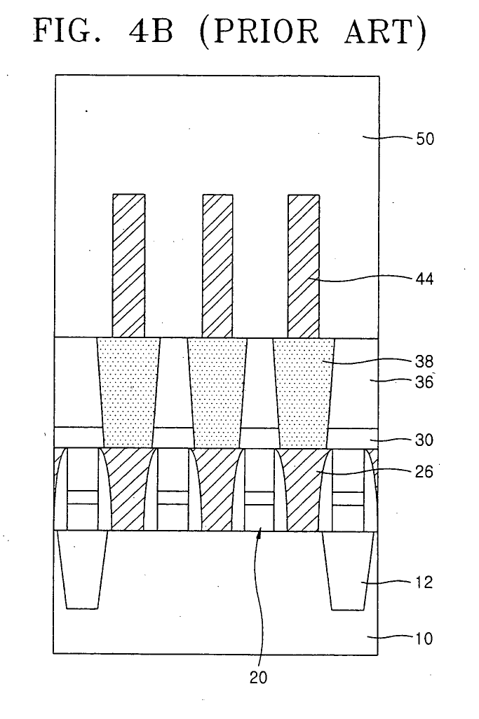

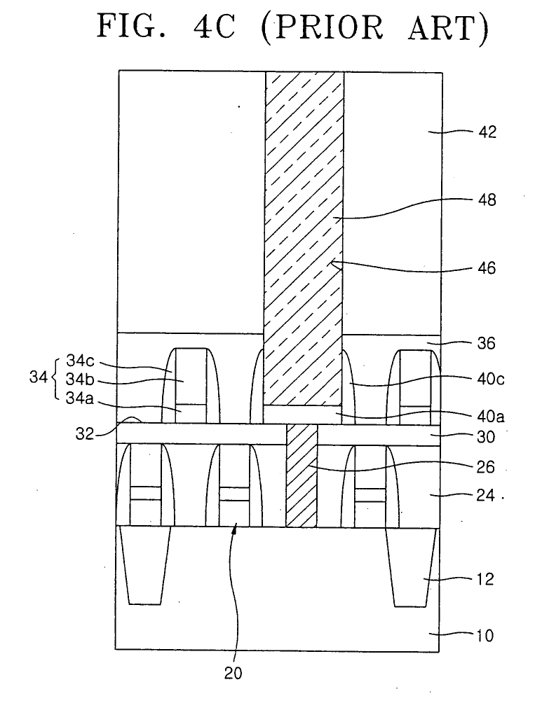

In alternative embodiments, the conductive stud 136 may partially cover an upper surface of the core bit line 132. By doing so, an upper surface area of the conductive stud 136 is enlarged, and thus a contact area for interconnection during subsequent processing can be increased. Moreover, because the core bit line 132 is wider than the bit line (34 of FIG. 1) of the conventional core region, the contact area can be further increased.

At the same time, a lower electrode contact 138 may be formed in the cell region, where the lower electrode contact is connected to the contact pad 114 by penetrating the third interlayer insulating layer 130 and the second interlayer insulating layer 120 between the cell bit lines 134.

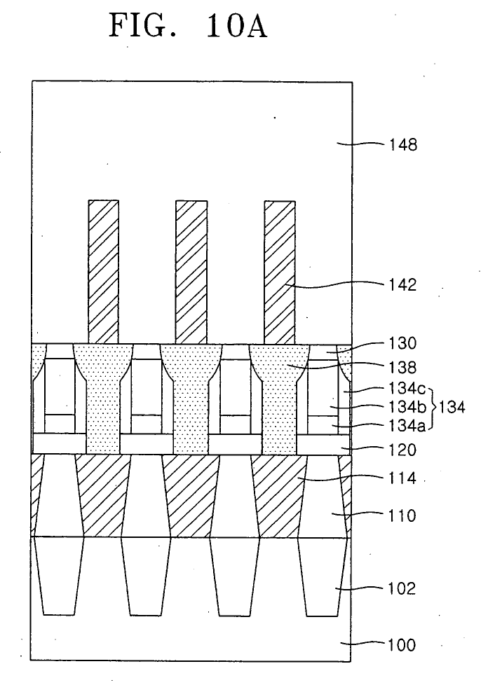

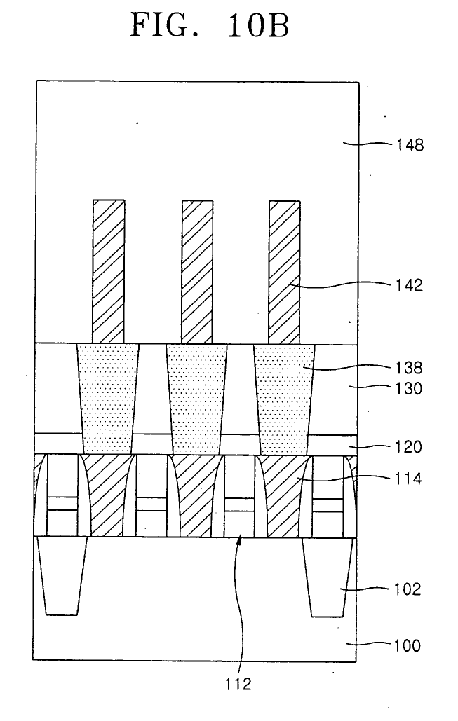

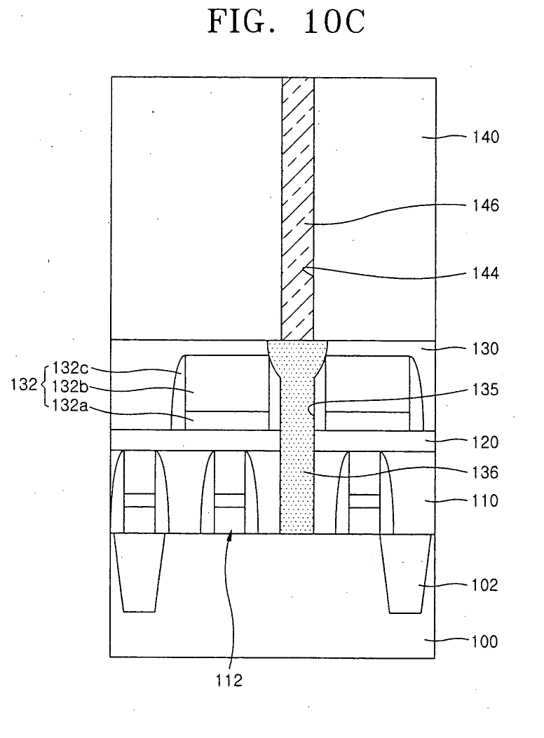

FIG. 9 is a plan diagram illustrating an interconnect contact 146 in the core region of FIG. 5 according to some embodiments-of the invention. FIG. 10A is a sectional diagram illustrating the cell region of FIG. 9 in a direction perpendicular to the word line. FIG. 10B is a sectional diagram illustrating the cell region of FIG. 9 in a direction perpendicular to the word line. FIG. 10C is a sectional diagram illustrating the contact portion of the core region of FIG. 9.

Referring to FIGS. 9, 10A, 10B, and 10C, an interconnect contact 146, which can be electrically connected to an external interconnect, is formed on the conductive stud 136 in the core region. When forming the interconnect contact 146, a fourth interlayer insulating layer 140 is formed on the third interlayer insulating layer 130 where the conductive stud 136 is already formed. Then, a second photoresist pattern (not shown) for defining the interconnect contact 146 is formed on the fourth interlayer insulating layer 140. Using the second photoresist pattern as an etch mask, a second contact hole 144 that exposes an upper surface of the conductive stud 136 is formed. The second contact hole 144 is filled with a conductive material, thereby forming the interconnect contact 146.

Simultaneously, a capacitor 142 may be formed on the lower electrode contact 138 in the cell region. Thereafter, a fifth interlayer insulating layer 148 that covers the capacitor 142 is formed. Because a sacrificial insulating layer may be used when forming the capacitor 142, the fifth interlayer insulating layer 148 covering the cell region may differ from the fourth interlayer insulating layer 140 that covers the core region.

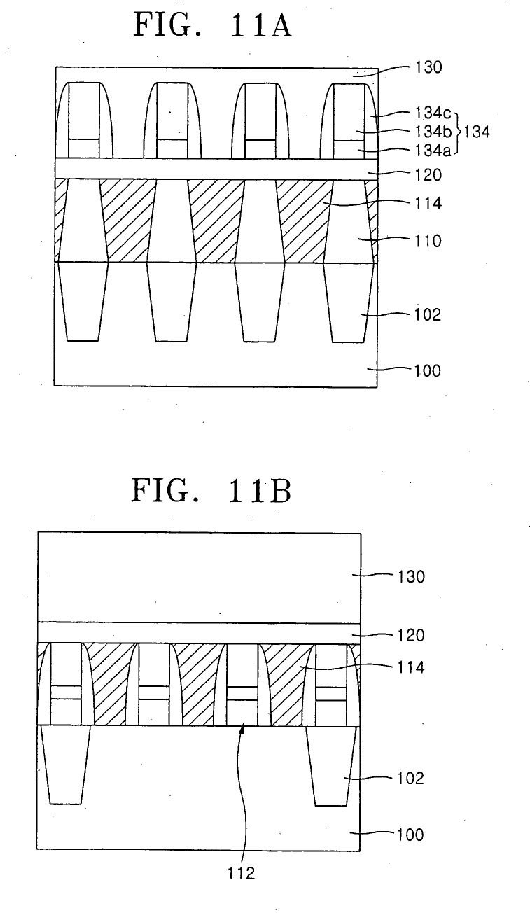

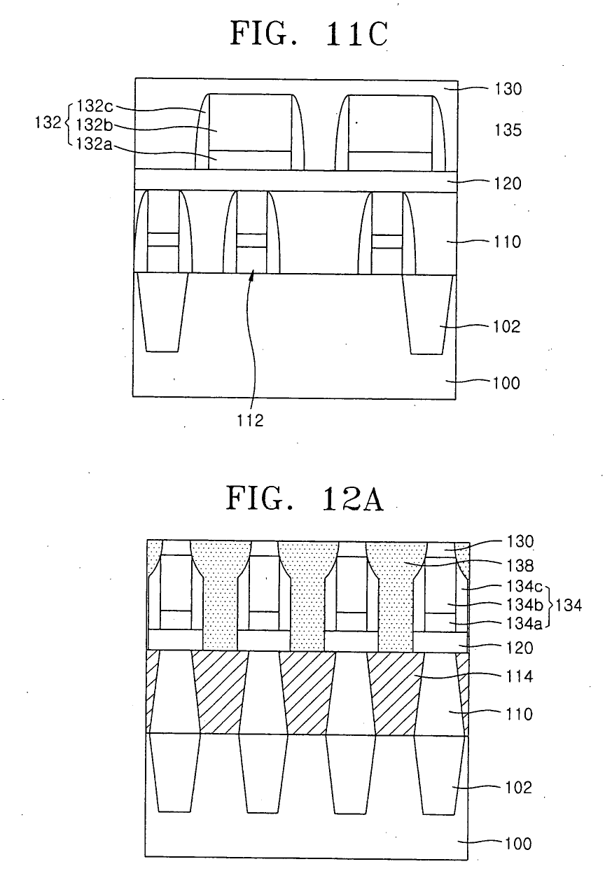

FIGS. 11A, 12A, and 13A are sectional diagrams illustrating a cell region of a semiconductor device according to other embodiments of invention in a direction perpendicular to a word line. FIGS. 11B, 12B, and 13B are sectional diagrams further illustrating the cell regions of FIGS. 11A, 12B, and 13B, respectively, but in a direction perpendicular to a bit line. FIGS. 11C, 12C, and 13C are sectional diagrams illustrating the contact portion of the core region of the semiconductor device illustrated in FIGS. 11A-11B, 12A-12B, and 13A-13B.

In the embodiments illustrated in FIGS. 11, 12, and 13, a conductive stud 136a is formed on a landing pad 210 that is disposed on the first interlayer insulating layer 110. The process of forming the interconnect contact 146 of the embodiments illustrated in FIGS. 11, 12, and 13 is similar to that of the embodiments that were describe above, and thus its detailed description will be omitted.

Referring to FIGS. 11A, 11B, and 11C, a device isolating layer 102 is formed within a semiconductor substrate 100 to define an active region. Then, a first interlayer insulating layer 110 covering a gate line 112 is formed on the semiconductor substrate 100. In the core region, a third photoresist pattern (not shown) for defining a landing pad 210 is formed on the first interlayer insulating layer 110. Using the third photoresist pattern as an etch mask, the first interlayer insulating layer 110 is etched, thereby forming a third contact hole 212 that exposes the semiconductor substrate 100. The third contact hole 212 is filled with a conductive material to form the landing pad 210.

Subsequently, a second interlayer insulating layer 120 is formed on the first interlayer insulating layer 110 where the landing pad 210 is disposed. Then, a core bit line 132 extending in a first direction is formed on the second interlayer insulating layer 120.

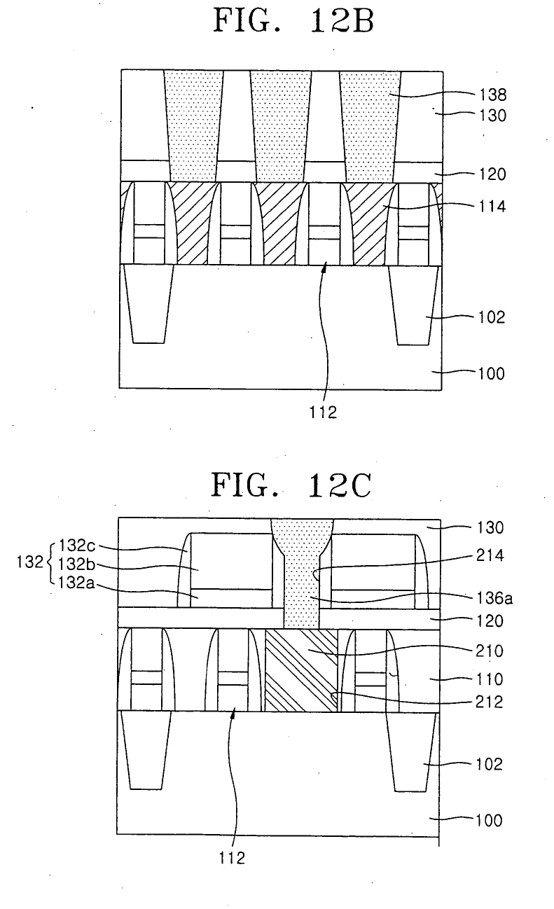

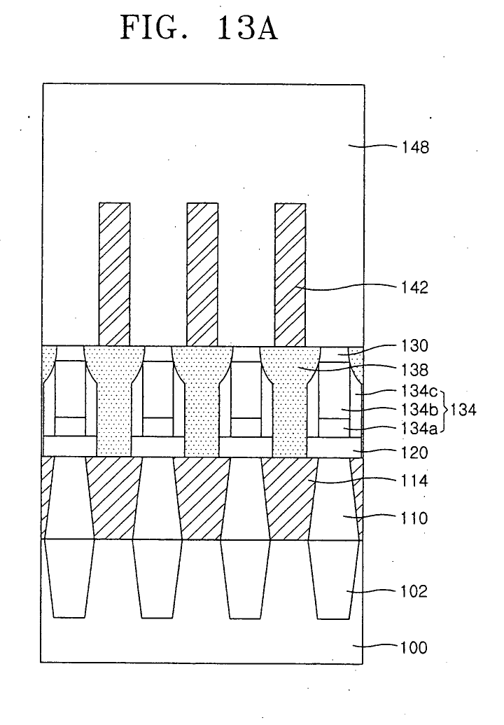

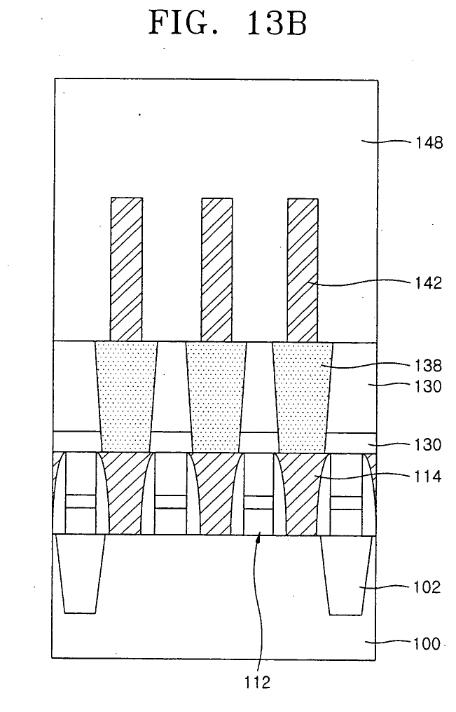

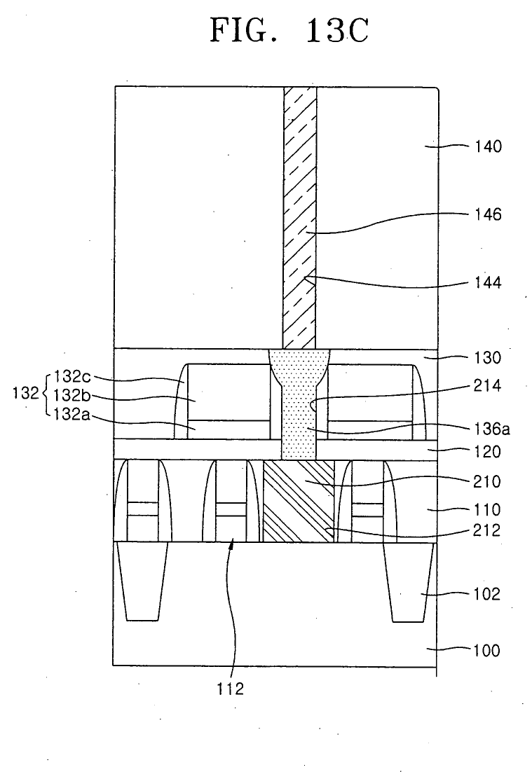

Referring to FIGS. 12A, 12B, and 12C, the conductive stud 136a (see above) is formed on the landing pad 210. When forming the conductive stud 136a, a third interlayer insulating layer 130 that covers the core bit line 132 is first formed. Thereafter, a fourth photoresist pattern (not shown) for forming the conductive stud 136a is formed on the third interlayer insulating layer 130. Using the fourth photoresist pattern as an etch mask, the third interlayer insulating layer 130 and the second interlayer insulating layer 120 between the core bit lines 132 are removed, thereby forming a fourth contact hole 214 (see FIGS. 12C and 13C) that exposes the landing pad 136a. The fourth contact hole 214 is filled with a conductive material to form the conductive stud 136a. The conductive stud 136a may pass through the first interlayer insulating layer 110 between the underlying gate lines 112.

According to the devices and methods described above, a conductive stud is connected to a semiconductor substrate by penetrating core bit lines of a core region. Therefore, an overlap margin between an interconnect contact and a core bit line can be increased.

Furthermore, the conductive stud is fabricated using self-alignment, thereby fabricating a semiconductor device with higher integration density.

The invention may be practiced in many ways. What follows are exemplary, non-limiting descriptions of some embodiments of the invention.

According to some embodiments, a semiconductor device having a contact includes a semiconductor substrate with a core region. A first interlayer insulating layer is formed on the semiconductor substrate, and a first interconnect line extends in a first direction on the first interlayer insulating layer. A conductive stud covers a sidewall of the first interconnect line, and penetrates a plurality of the first interconnect lines to contact the semiconductor substrate.

A core bit line may be connected to a cell bit line of a cell region, in which the cell bit line is narrower than the first interconnect line.

The conductive stud may be self-aligned between the first interconnect lines. The conductive stud further may include an interconnect contact electrically connected to an external interconnect. Furthermore, the conductive stud may have a landing pad within the underlying first interlayer insulating layer to electrically connect to the semiconductor substrate.

According to some embodiments, a method of fabricating a semiconductor device having a contact includes forming a first interlayer insulating layer on a semiconductor substrate of a core region. After forming a first interconnect line on the first interlayer insulating layer and extending in a first direction, a conductive stud contacting the semiconductor substrate is formed to penetrate a plurality of the first interconnect lines, and to cover a sidewall of the first interconnect line.

Forming the conductive stud may include forming a third interlayer insulating layer that covers the bit line, and forming a photoresist pattern for forming the conductive stud on the third interlayer insulating layer. Using the photoresist pattern as an etch mask, a first contact hole that exposes the semiconductor substrate is formed by removing the third interlayer insulating layer and the first interlayer insulating layer between the bit lines. Then, the conductive stud is formed by burying a conductive material in the first contact hole.

Before forming the conductive stud, a landing pad may be formed within the first interlayer insulating layer to electrically connect the conductive stud to the semiconductor substrate.

An overlap margin between an interconnect contact and an interconnect line, e.g., a bit line, in a core region of a semiconductor device can be increased by using a contact in accordance with embodiments of the invention or a method of fabricating the contact in accordance with embodiments of the invention. In the semiconductor device, a first interconnect line extending in a first direction is disposed on a first interlayer insulating layer formed on the semiconductor substrate. Also, a conductive stud covering a sidewall of the first interconnect line penetrates a portion between a plurality of the first interconnect lines to contact the semiconductor substrate. The contact can increase the overlap margin between the interconnect contact and the first interconnect lines such that the conductive stud penetrates the first interconnect lines of the core region to be connected to the semiconductor substrate.

While the invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor device having a contact, the semiconductor device comprising:
a semiconductor substrate having a core region;
a first interlayer insulating layer disposed on the semiconductor substrate;
a first interconnect line disposed on the first interlayer insulating layer, the first interconnect line extending in a first direction; and
a conductive stud covering a sidewall of the first interconnect line, the conductive stud penetrating the first interlayer insulating layer to contact the semiconductor substrate.

2. The semiconductor device of claim 1, the first interconnect line comprising a bit line formed in the core region.

3. The semiconductor device of claim 1, the first interconnect line connected to a second interconnect line in a cell region of the semiconductor substrate, the second interconnect line narrower than the first interconnect line.

4. The semiconductor device of claim 1, further comprising a gate line covered by the first interlayer insulating layer, the gate line extending on the semiconductor substrate in the first direction.

5. The semiconductor device of claim 4, the conductive stud penetrating through the first interlayer insulating layer between the gate line and another gate line.

6. The semiconductor device of claim 4, further comprising a second interlayer insulating layer disposed between the first interlayer insulating layer and the first interconnect line.

7. The semiconductor device of claim 1, the conductive stud self-aligned between the first interconnect lines.

8. The semiconductor device of claim 1, the conductive stud further comprising an interconnect contact that is electrically connected to an external interconnect.

9. The semiconductor device of claim 1, the conductive stud further comprising a landing pad surrounded by the first interlayer insulating layer, the landing pad contiguous with an upper surface of the semiconductor substrate, a width of the landing pad greater than a width of the conductive stud.

10. A method of fabricating a semiconductor device having a contact, the method comprising:
forming a first interlayer insulating layer on a core region of a semiconductor substrate;
forming a first interconnect line on the first interlayer insulating layer, the first interconnect line extending in a first direction; and
covering a sidewall of the first interconnect line with a conductive stud that penetrates the first interlayer insulating layer to contact the semiconductor substrate.

11. The method of claim 10, further comprising, before forming the first interlayer insulating layer, forming a gate line that extends in the first direction, the gate line contiguous with an upper surface of the semiconductor substrate.

12. The method of claim 11, further comprising, after forming the first interlayer insulating layer but before forming the first interconnect line, forming a second interlayer insulating layer on the first interlayer insulating layer.

13. The method of claim 10, further comprising forming a second interconnect line on a cell region of the semiconductor substrate concurrently with forming the first interconnect line on the core region, the second interconnect line connected to the first interconnect line, the second interconnect line narrower than the first interconnect line.

14. The method of claim 10, wherein covering the sidewall of the first interconnect line with the conductive stud comprises:
forming a third interlayer insulating layer that covers the first interconnect line;
forming a photoresist pattern on the third interlayer insulating layer;
etching the third interlayer insulating layer and the first interlayer insulating layer using the photoresist pattern as an etch mask to form a first contact hole that exposes the semiconductor substrate; and
filling the first contact hole with a conductive material to form the conductive stud.

15. The method of claim 14, further comprising, when forming the conductive stud, simultaneously forming a lower electrode contact in the cell region which penetrates the third interlayer insulating layer between the first interconnect lines.

16. The method of claim 10, further comprising, after forming the conductive stud, forming an interconnect contact for electrically connecting the conductive stud to an external device.

17. The method of claim 10, further comprising, before forming the conductive stud, forming a landing pad within the first interlayer insulating layer to electrically connect the conductive stud to the semiconductor substrate.
